(19) United States
(12) Patent Application Publication
(10) Pub. No.: US 2002/0121911 A1
(43) Pub. Date: Sep. 5, 2002

(54) Wafer level probe card

(76) Inventors: Wen-Kun Yang, Hsinchui (TW); David Wang, Hsinchu (TW); Chien Jen Tung, Kaohsiung (TW); Tomson Wu, Hsinchu (TW)

Correspondence Address: Chun M. Ng, BLAKELY, SOKOLOFF, TAYLOR & ZAFMAN LLP, 12400 Wilshire Boulevard, Seventh Floor, Los Angeles, CA, 90025-1026, US

(21) Appl. No.: 09/883,042

(22) Filed: Jun. 11, 2001

(30) Foreign Application Priority Data
Mar. 2, 2001 (TW) 90104943

(51) Int. Cl. G01R 31/02

(52) U.S. Cl. 324/754

(57) ABSTRACT

The present invention comprises a probe card having a cavity formed on the lower surface of the probe card. A buffer is formed in the cavity to act as cushion and a flexible circuit board is attached on the probe card surface that faces to the testing object. A probe is formed on the flexible circuit board, insulation material is formed on the flexible circuit board to fix the probe. Conductive material is coated on the probe to enhance the strength of the probe.

### FIELD OF THE INVENTION

The present invention relates to a semiconductor package testing, and more specifically, to a probe card for wafer level package.

### BACKGROUND OF THE INVENTION

With the rapid advances in the semiconductor package for semiconductor technology, designers are always tempted to scale the size of the package. The industry of the package is striving to reduce the size while simultaneously increasing their speed. The renewed interest in high density hybrid is driven by the requirement to handle large numbers of IC interconnections, the increasing clock rate of digital systems and the desire to pack greater functionality into smaller spaces. Therefore, the number of a package's leads becomes more and more. Generally speaking, the die is encapsulated in plastic or ceramic molded body. The pin configuration is changed from periphery structure to matrix array. The testing means is also modified to meet the requirement.

A conventional package technology involves the lead frame package that uses the leads as the signal input and output. Under the consideration of high pin count requirement, the lead frame has a limitation to increase the number of the package's lead. In addition, the maximum speed of the lead frame package can not meet the manufacturers' desire. One response to the requirement of providing packages for high speed and density devices has been developed. One such package type is ball grid array (BGA) for high I/O count IC dies. This type of structure provides more I/Os than lead frame type package or other type of package. BGAs connect to PCBs using bumps or balls instead of pins or leads, which are set on a package surface in a matrix array. For example, solder bumps are attached to the lower surface of a substrate. These bumps or balls, in turn, provide the I/O connections of the BGA package. Such a configuration allows an increase in the number of I/O interconnects over conventional packages. The BGA package has high speed due to a short path for signal transformation.

No matter what type of the package is, most of the packages are divided into individual chips before they are packaged. However, the wafer level packaging is a trend for the semiconductor package. U.S. Pat. No. 5,323,051, entitled “Semiconductor wafer level package” disclosed a newer trend for the package called wafer level package. In the technology, the die is tested and packaged in the entire wafer, followed by dicing the wafer into individual package units.

Base on the wafer level package, there is a need for developing the means for wafer level testing and testing method for the wafer level package. The first step to test the prior BGA is to separate the die from the wafer, and then the die is set in a testing socket for test. Each socket may only perform one die testing, it is impossible to test the dies in batch. However, the wafer level technology can achieve the advantage and the method will reduce the cost.

What is needed is a testing probe card for wafer level package.

### SUMMARY OF THE INVENTION

The object of the present invention is to provide a wafer level probe card.

The wafer level probe card comprises a probe card having a cavity formed on the lower surface of the probe card. A buffer is formed in the cavity to act as cushion and a flexible circuit board is attached on the probe card surface that faces to the testing object. A probe is formed on the flexible circuit board, insulation material is formed on the flexible circuit board to fix the probe. Conductive material is coated on the probe to enhance the strength of the probe.

The buffer and the insulation material are formed of epoxy. The probe includes copper or copper alloy. Further, the flexible circuit board includes printed circuit formed thereon and through hole formed therein to form signal communication path. The probe card includes pogo pin aligned to the through hole.

### BRIEF DESCRIPTION OF THE DRAWINGS

FIG. 1 is a cross section view of a structure according to the embodiment of the present invention.

FIG. 2 is a portion of the probe card according to the present invention.

FIG. 3 is a cross section view of a structure according to the present invention.

FIG. 4 shows the major configuration of the probe card according to the present invention.

FIG. 5 shows the cross section view of the probe according to the present invention.

### DETAILED DESCRIPTION OF THE PREFERRED EMBODIMENT

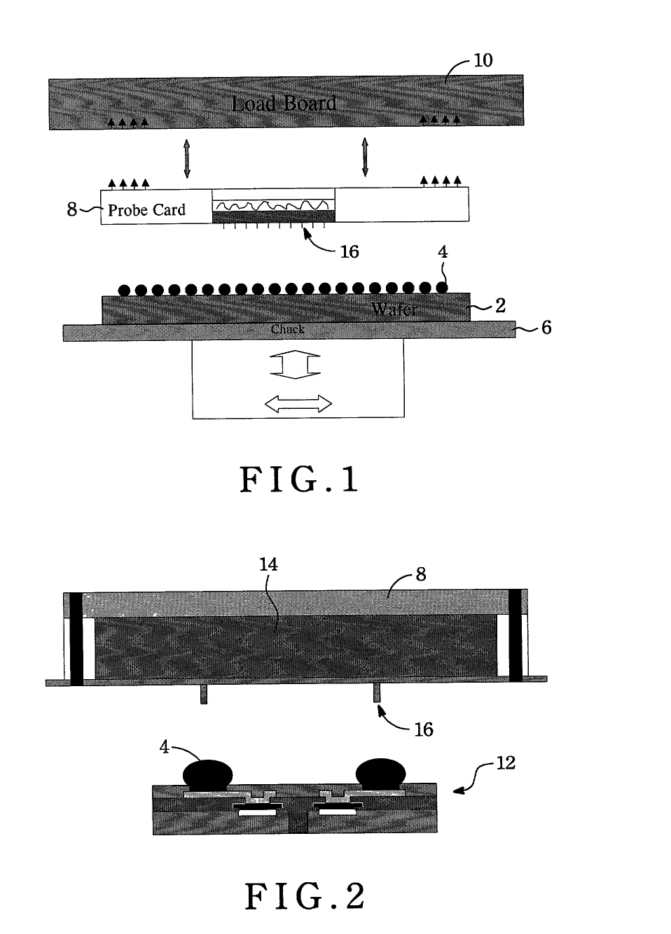

The particular wafer level probe card shown in FIG. 1 is related to wafer level package technology. But it should also be understood that the present invention is not limited to this particular type of package.

Referring to FIG. 1, a wafer 2 is provided and a plurality of device and IC are formed therein. A plurality of conductive bumps 4 are also formed on the surface of the wafer 2 for signal communication. A vacuum chuck 6 is used to fix the wafer 2 by pressure difference between both sides of the wafer. A testing card 8 contacts to the conductive bumps 4 formed on the wafer 2 by using probe, thereby forming the testing path. The testing card 8 includes probe 16 and circuits formed thereof and the probe 16 may be formed of membrane tip. A load board 10 is attached on the probe card 8 for transferring the testing signal to the testing apparatus for analysis.

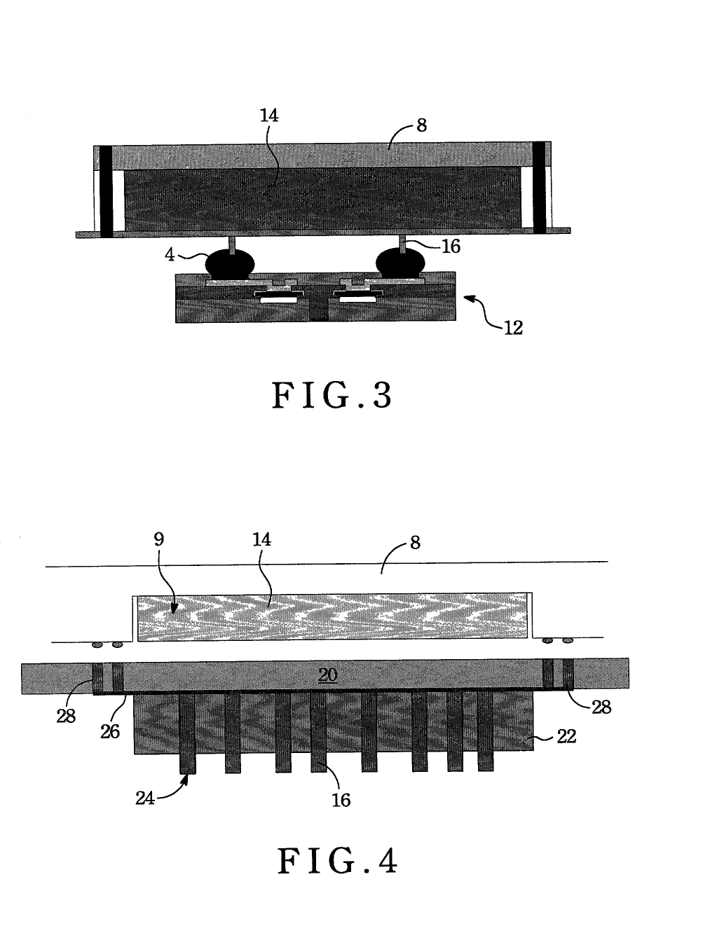

Turning to FIG. 2, it shows a part of the cross section structure of the probe card 8. FIG. 3 illustrates the situation when the probe 16 contacts to the conductive bumps 4. The membrane tips contact to the conductive bumps 4 of each unit 12 on the wafer 2. The unit 12 indicates a portion of the wafer 2 and the units 12 have to be tested and packaged prior to they are separated. Further, the present invention may be applied to the probing pad or bonding pad of the un-packed wafer.

Referring to FIG. 4, it illustrates the major configuration of the probe card 8. The wafer level probe card includes the probe card 8 that is used to carry the member of the device. The probe card 8 includes a cavity or hole 9 formed on the lower surface of the probe card 8 and inwardly indented into the probe card 8. A buffer 14 is received and attached in the cavity 9 to act as cushion to absorb the external force from the testing object. Preferably, the buffer 14 can be formed of epoxy or rubber. A flexible circuit board 20 is attached to the probe card's surface with the buffer 14 and faces to the testing object. The probes 20 on the flexible circuit board 20 are formed by means of semiconductor process and the probes 20 are fixed by insulator material 22. In preferred embodiment, the insulator material 22 includes but not limited to epoxy or silicone. The surface of the probe 16 is coated with hard conductive material 24 to enhance the strength of the probe 16. The flexible circuit board 20 includes printed circuits 26 with PI substtrate formed thereon and through hole 28 formed therein to construct the path for signal communication. The above through hole 28 is aligned to the pogo pin 30 of the probe card 8 in order to transfer the signal.

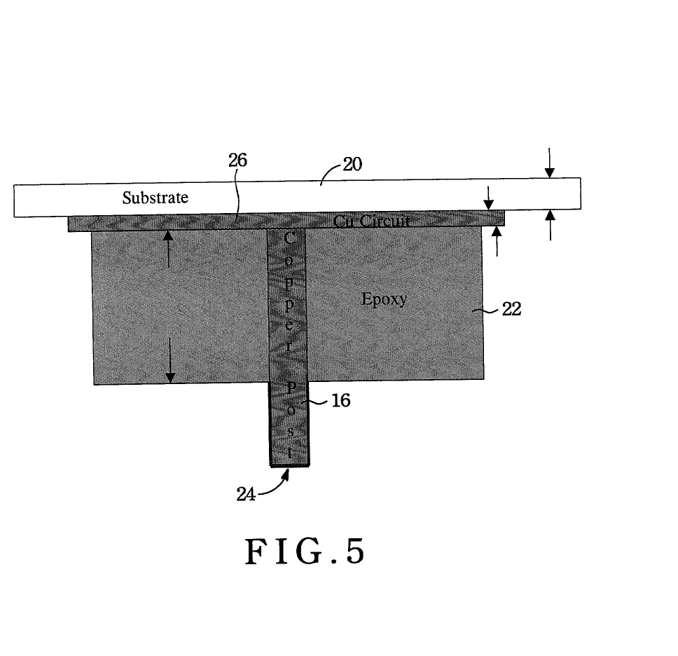

Turning to FIG. 5, the probe 16 is composed of copper or copper alloy, the printed circuits 26 on the flexible circuit board 20 is also formed of copper or copper alloy. The coated material 24 on the probe surface is used to protect the probe 16 and can be formed by electroplate technology.

The making of the wafer level probe card includes: forming a buffer 14 in the cavity 9 of the probe card 8; placing the flexible circuit board 20 on the lower surface of the probe card;

forming the probe 16 on the flexible circuit board 20; forming the coated material 24 on the probe 16 to enhance the strength of the probe 16 and increase the life of the probe 16.

The method of forming the probe includes patterning phtoresist on the substrate and then etched the substrate. A conductive material is formed in the etched substrate, then the photoresist is removed, thereby forming the conductive pin on the substrate. Thereafter, the coated material is formed on the surface of the probe.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure. Thus, while the preferred embodiment of the invention has been illustrated and described, it will be appreciated that various changes can be made therein without departing from the spirit and scope of the invention.

The embodiments of the invention in which an exclusive property or privilege is claimed are defined as follows:

1. A wafer level probe card comprising:
a probe card having a cavity or hole formed on the lower surface of the probe card;
a buffer formed in said cavity to act as cushion;
a flexible circuit board attached on said probe card surface that faces to the testing object;
a probe formed on said flexible circuit board;
insulation material formed on said flexible circuit board to fix said probe; and
conductive material coated on said probe to enhance the strength of said probe.

2. The wafer level probe card of claim 1, wherein said buffer includes epoxy or rubber.

3. The wafer level probe card of claim 1, wherein said insulation material includes epoxy or silicone.

4. The wafer level probe card of claim 1, wherein said probe includes copper.

5. The wafer level probe card of claim 1, wherein said probe includes copper alloy.

6. The wafer level probe card of claim 1, wherein said conductive material includes metal.

7. The wafer level probe card of claim 1, wherein said flexible circuit board includes printed circuit with PI substrate formed thereon and through hole formed therein to form signal communication path.

8. The wafer level probe card of claim 7, wherein said probe card includes pogo pin aligned to said through hole.

9. The wafer level probe card of claim 7, wherein said conductive material is coated by electroplates.
